(19) United States
(12) Patent Application Publication
(10) Pub. No.: US 2006/0054970 A1
(43) Pub. Date: Mar. 16, 2006

(54) Semiconductor device and method of manufacturing the same

(75) Inventors: Masamichi Yanagida, Ota-city (JP); Hirotoshi Kubo, Ora-gun (JP); Junichiro Tojo, Ota-Shi (JP); Hiraoki Saito, Ota-shi (JP); Masahito Onda, Ora-Gun (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Moriguchi-Shi (JP)

(21) Appl. No.: 11/220,406

(22) Filed: Sep. 7, 2005

(30) Foreign Application Priority Data
Sep. 8, 2004 (JP) 2004-260533

(51) Int. Cl. H01L 29/94

(52) U.S. Cl. 257/330

(57) ABSTRACT

In an embodiment of the present invention, after trenches, a gate oxide film and gate electrodes are formed, a channel layer is formed by plural high-acceleration ion implantations where acceleration voltages are different with one another. The channel layer is an impurity implanted layer on which diffusion by a heat treatment is not performed. The channel layer is allowed to have its impurity concentration substantially uniform in a depth-wise direction of the trenches, by implanting ions of the impurity at plural different times by use of a high-acceleration ion implantation system. Since a second region having almost no influence on a characteristic of the channel layer can be reduced, the channel layer having a minimum necessary depth can be obtained. The trenches are thus made shallow, and accordingly a capacitance can be reduced. Furthermore, an on resistance can be made lower by making an epitaxial layer thinner.

### BACKGROUND OF THE INVENTION

1. Field of the Invention

The present invention relates to a semiconductor device and to a method of manufacturing the same, and particularly to a semiconductor device in which a channel layer has a shallow impurity concentration profile and to a method of manufacturing the same.

2. Description of the Related Art

With regard to a semiconductor device of an insulated gate type, a more minute and thinner configuration thereof is being pursued by employing a trench structure. FIG. 10 is a cross-sectional view of a conventional semiconductor device, and shows a MOSFET of an n-channel type trench structure, as an example.

A substrate 20 is provided in such a manner that an n⁻ type epitaxial layer 22 to be a drain region is stacked on an n⁺ type silicon semiconductor substrate 21. A p type channel layer 24 is then provided on the surface of the drain region 22.

Trenches 27 are provided in a manner that each of them penetrates the channel layer 24 and reaches the drain region 22. An inner wall of each of the trenches 27 is coated with a gate oxide film 31. Gate electrodes 33, each of which is formed of polysilicon filled in each of the trenches 27, are provided.

On a surface of the channel layer 24, next to each of the trenches 27, an n⁺ type source region 35 is provided. A p⁺ type body region 34 is arranged on the surface of the channel layer 24, between each two adjacent cells of the n⁺ type source regions 35. Furthermore, channel regions (not illustrated) are formed along the trenches 27 from the respective source regions 35, when a voltage is applied to the gate electrodes 33. Tops of the gate electrodes are covered with interlayer insulating films 36. A barrier metal layer (not illustrated) is contacted with the source regions 35 and the body regions 34 which are exposed through contact holes CH each located between two adjacent ones of the interlayer insulating films 36, and a metal wiring layer (source electrode) 38 is provided on the barrier metal layer.

With reference to FIGS. 11A to 14, a description will be given of a method of manufacturing the conventional semiconductor device.

In FIG. 11A, a drain region 22 is formed by stacking an n⁻ type epitaxial layer on an n⁺ type silicon semiconductor substrate 21. After an oxide film (not illustrated) is formed on a surface of the drain region 22, portions of the oxide film, which correspond to those where a channel layer is to be formed, are etched. By using the oxide film as a mask, boron, for example, is implanted into the whole top surface by such a level of a dose as 1.0×10¹² to 1.0×10¹³ cm⁻², and with an implantation energy of about 30 keV. Afterward, the implanted boron is diffused by a heat treatment taking a few to several hours to form a p type channel layer as shown in FIG. 11B.

In FIG. 12, trenches 27, each of which penetrates the channel layer 24 and reaches the drain region 22, are formed by dry etching the silicon semiconductor substrate by use of CF-based gas and HBr-based gas, with a mask (not illustrated) provided on the whole top surface, the mask being formed of a CVD oxide film of NSG (non-doped silicate glass).

In FIG. 13, first, etching damages generated in dry etching are removed by applying dummy oxidation to form a dummy oxide film on an inner wall and on a surface of the channel layer 24. A stable gate oxide film can be formed by simultaneously removing the dummy oxide film thus formed by dummy oxidation and the CVD oxide film by use of an oxide film etchant such as hydrofluoric acid. In addition, an effect of avoiding concentration of electric fields at an opening portion of each of the trenches 27 is obtained since thermal oxidation under a high temperature allows the opening portion thereof to be rounded off. Afterward, a gate oxide film 31 is formed, that is, a gate oxide film 31 is formed by thermally oxidizing the whole top surface in order for the gate oxide film 31 to have a thickness of a few to several hundred angstroms in accordance with a threshold voltage value.

Next, on the whole top surface, a non-doped polysilicon is stacked, and boron is implanted and diffused so as to have a high boron concentration for the purpose of achieving a high conductivity. A gate electrode 33 embedded in each of the trenches 27 remains after the polysilicon layer is dry etched without using a mask.

In FIG. 14, body regions 34, which serve to give stability to a potential of the substrate, and source regions 35 are formed. First, ions of a p type impurity such as boron are selectively implanted, by using a mask formed of a resist film, to the regions where the body regions 34 are intended to be formed, and then the resist film is removed. Additionally, ions of an n type impurity such as arsenic are implanted by using another resist film as a mask which covers the whole top surface but exposes the gate electrodes 33 and regions where the source regions 35 are intended to be formed. Then, the resist film is removed.

Next, an insulating film, such as BPSG (boron phosphorus silicate glass) and a multilayered film, which are to form an interlayer insulating film, are stacked on the whole top surface by means of such a method as a CVD method. Then, the n type impurity and the p type impurity that are implanted into the top surface of the channel layer 24 are diffused, and thereby formed are the n⁺ type source regions 35 each of which is adjacent to one of the trenches 27, and the p⁺ type body regions 34 each of which is located between adjacent two of the source regions 35.

Then, an interlayer insulating film is etched by using a resist layer as a mask. In that way, an interlayer insulating film 36 is allowed to remain at least on each of the gate electrodes 33, and at the same time, contact holes CH, through which the n⁺ type source regions 35 and p⁺ type body regions 34 contact with a metal wiring layer 38, are formed.

Furthermore, a high-melting point metal layer (not illustrated), which becomes a barrier metal layer by using a titan-based material (Ti/TiN or the like), is formed. Subsequently, a final structure as shown in FIG. 10 is obtained by spattering aluminum alloy, which forms the metal wiring layer 38, onto the whole top surface. (This technology is described for instance in Japanese Patent Application publication No. 2002-343805.)

### SUMMARY OF THE INVENTION

The invention provides a semiconductor device that includes a semiconductor substrate, a drain region disposed on the semiconductor substrate, a channel layer disposed on the drain region, a trench penetrating the channel layer to reach the drain region, a gate electrode disposed in the trench, an insulating film disposed between an inner wall of the trench and the gate electrode, and a source region formed in the channel layer and adjacent the trench, wherein an impurity concentration profile of the channel layer in a depth direction thereof has a peak or a flat peak region, and a distance between a bottom of the source region and the peak or an bottom end of the flat peak region is larger than a distance between an bottom of the channel layer and the peak or the bottom end of the flat peak region.

The invention also provides a method of manufacturing a semiconductor device that includes providing a semiconductor substrate of a first general conductivity type, depositing a semiconductor layer of the first general conductivity type on the semiconductor substrate, forming a trench in the semiconductor layer, forming an insulation film to cover an inner wall of the trench, forming a gate electrode in the trench covered by the insulation film, performing a first impurity implantation of the semiconductor layer after the formation of the gate electrode, performing a second impurity implantation of the semiconductor layer after the first impurity implantation, and forming a region of the first general conductivity type in the semiconductor layer and adjacent the trench, wherein the first and second impurity implantations are performed so that a channel layer of a second general conductivity type is formed in the semiconductor layer with no heat treatment to diffuse implanted impurities further into the semiconductor layer.

### BRIEF DESCRIPTION OF THE DRAWINGS

FIGS. 1A and 1B are cross-sectional views explaining a semiconductor device according to an embodiment of the invention.

FIG. 2 is a cross-sectional view explaining a method of manufacturing a semiconductor device according to the embodiment of the invention.

FIG. 3 is a cross-sectional view explaining the method of manufacturing the semiconductor device according to the embodiment of the invention.

FIG. 4 is a cross-sectional view explaining the method of manufacturing the semiconductor device according to the embodiment of the invention.

FIGS. 5A, 5B and 5C are cross-sectional views explaining the method of manufacturing the semiconductor device according to the embodiment of the invention.

FIGS. 6A, 6B and 6C are cross-sectional views explaining the method of manufacturing the semiconductor device according to the embodiment of the invention.

FIG. 7 is a cross-sectional view explaining the method of manufacturing the semiconductor device according to the embodiment of the invention.

FIGS. 8A and 8B are characteristic charts explaining respectively a conventional semiconductor device and the semiconductor device according to the embodiment of the invention.

FIGS. 9A and 9B are characteristic charts explaining the semiconductor device according to the embodiment of the invention.

FIG. 10 is a cross-sectional view explaining the conventional semiconductor device.

FIGS. 11A and 11B are cross-sectional views explaining the method of manufacturing the conventional semiconductor device.

FIG. 12 is a cross-sectional view explaining the method of manufacturing the conventional semiconductor device.

FIG. 13 is a cross-sectional view explaining the method of manufacturing the conventional semiconductor device.

FIG. 14 is a cross-sectional view explaining the method of manufacturing the conventional semiconductor device.

FIGS. 15A and 15B are, respectively, a characteristic chart and a cross-sectional view, each explaining the conventional semiconductor device.

### DESCRIPTION OF THE PREFERRED EMBODIMENTS

In the conventional semiconductor device, as described above, the channel layer 24 is provided to have a substantially uniform depth from a top surface of the n⁻ type epitaxial layer 22, by implanting and diffusing ions. In addition, in the method of manufacturing the conventional semiconductor device, after a step where an ion implantation of the impurity is carried out only at one time, the channel layer 24 is formed in a way that the impurity is diffused by applying a heat treatment for a few to several hours, and afterward, the trenches 27 and the gate oxide film 31 are formed.

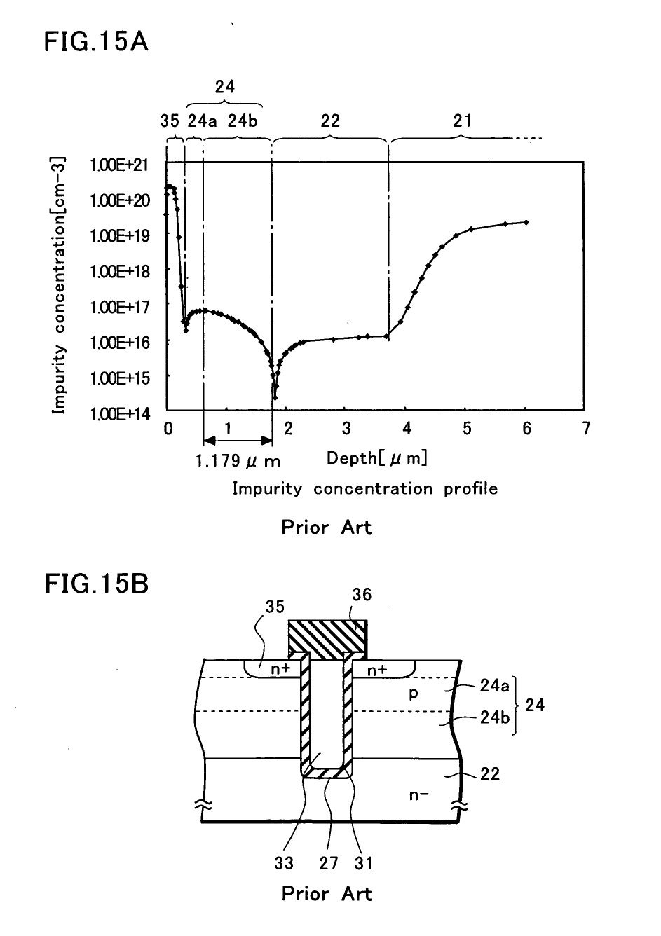

With reference to FIGS. 15A and 15B, the channel layer 24 having a conventional configuration will be described. FIG. 15A is an impurity concentration profile of each of the source regions 35, the channel layer 24, the n⁻ type epitaxial layer 22, and the semiconductor substrate 21, which are of the conventional configuration. The longitudinal and lateral axes respectively indicate an impurity concentration and a depth from the top surface of the n⁻ type epitaxial layer 22. In addition, FIG. 15B is an enlarged cross-sectional view of an MOSFET.

An impurity concentration profile of the channel layer 24 results in a shape shown in FIG. 15A. Here, a portion below the source regions 35 is defined as the channel layer 24. Additionally, the depth from the interface between the channel layer 24 and the source regions 35 to a mean projected range of the impurity concentration profile, which is the peak of the impurity concentration distribution, defines a first region 24a. Furthermore, the rest of the channel layer 24 below the first region 24a is defined as a second region 24b. The second region 24b has a negative gradient in the impurity profile, which is smaller in magnitude than that in the first region 24a. In FIG. 15B, the first region 24a the second region 24b are schematically shown.

An impurity concentration needed by the channel layer 24 is such an impurity concentration that can suppress a leak current and is approximately 1×10¹⁷ cm⁻³. Here, in order that, as in the conventional case, the above impurity concentration can be diffused to reach a predetermined depth (in accordance with a characteristic of the channel layer 24, for example, 0.8 μm or less from the top surface of the substrate 20) with a relatively low implantation energy (approximately 30 keV), it is necessary to apply a heat treatment for a few to several hours. With the heat treatment for such a long time, the impurity diffusion progresses in a depth-wise direction of the substrate, resulting in formation of the second region 24b which has a slow concentration gradient as shown in the drawing.

However, in the second region 24b, a particularly lightly doped region (approximately 1×10¹⁵ to 1×10¹⁶ cm⁻³) is a region which has almost no influence on a substantial characteristic of the channel layer 24, i.e., which is not needed by the channel layer 24. Meanwhile, although the second region 24b has almost no influence on the substantial characteristic since the impurity concentration thereof slowly decreases, it has an influence on the depth of the channel layer 24. As a result, although it is sufficient for the channel layer 24 to have a depth of approximately 1 μm, which is required to obtain an impurity concentration needed by the channel layer 24, the depth of the channel layer 24 becomes approximately 2 μm from its top surface of the substrate 20.

If the channel layer 24 is formed needlessly deeply, that requires the trenches 27 to be formed deeply as well, and accordingly inhibits a lower capacitance of the MOSFET. In addition, since the n- type epitaxial layer 22 of a predetermined thickness (depth) has to be secured below the channel layer 24 in order to secure a predetermined breakdown voltage, there has been a problem that a reduction in on resistance is scarcely brought about.

However, the second region 24b is a by-product of the heat treatment, and it has been uncontrollable in the conventional methods.

Furthermore, the dummy oxidation process and the process of gate oxide film 31 formation, which follow the formation of the trenches 27, are thermal oxidation at high temperatures of 1000° C. or higher. Therefore, boron as the impurity is reduced in the channel layer 24 where the channel layer 24 contacts each of the trenches 27 as a result of depletion. Accordingly, the impurity concentration around each of the trenches 27 is reduced, and there has been a problem that variation in the impurity concentration profile is increased thereby.

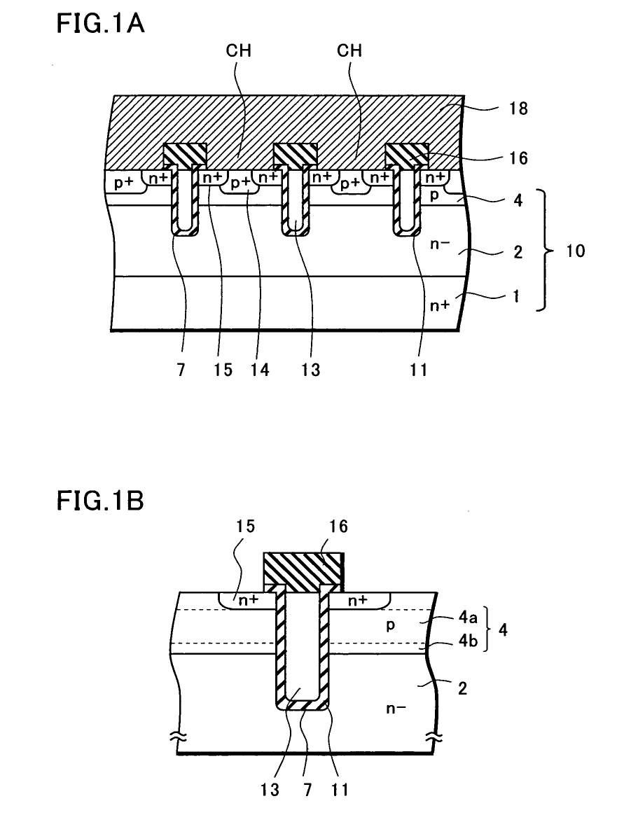

With reference to FIGS. 1A to 9B, an embodiment of the present invention will be described by taking as an example of an MOSFET having an n-channel type trench structure.

FIGS. 1A and 1B are cross-sectional views showing a structure of the MOSFET. FIG. 1A is a cross-sectional view showing a plurality of cells. FIG. 1B is an enlarged view of a part of FIG. 1A.

The MOSFET includes a semiconductor substrate 1, a semiconductor layer 2, trenches 7, a channel layer 4, gate electrodes 13 and source regions 15.

A substrate 10 is provided by, for example, stacking an n⁻ type epitaxial layer 2 to be a drain region on an n⁺ type silicon semiconductor substrate 1. On a top surface of the substrate 10, a p type channel layer 4 is provided.

The trenches 7 are provided in a manner that each of them penetrates the channel layer 4 and reaches the drain region 2. An inner wall of each of the trenches 7 is coated with a gate oxide film 11. Then, the gate electrodes 13, which are formed of polysilicon filled in the respective trenches 7, are provided.

On the top surface of the channel layer 4, an n⁺ type source region 15 is provided next to each of the trenches 7, and on the top surface of the channel layer 4, a p⁺ type body region 14 is provided between two adjacent ones of the source regions 15. Thereby, when a voltage is applied to the gate electrodes 13, channel regions (not illustrated) are formed along the respective trenches 7 from the respective source regions 15. Top surfaces of the respective gate electrodes 13 are covered with interlayer insulating films 16. Portions between two adjacent ones of the interlayer insulating films 16 become contact holes CH through which the n⁺ type source regions 15 and the p+ type body regions 14 contact with a metal wiring layer 18. The source regions 15 and the body regions 14, which are exposed through the contact holes CH, are electrically connected through a barrier metal layer (not illustrated) to the metal wiring layer (a source electrode) 18 formed of aluminum alloy or the like.

The channel layer 4 is an impurity-ion implanted layer, and is provided so as to have a substantially uniform depth from the top surface of the n⁻ type epitaxial layer 2. While the channel layer 4 is formed from the top surface of the n⁻ type epitaxial layer 2, the source regions 15 are provided onto the top surface of the channel layer 4. The channel layer 4 includes a first region 4a and a second region 4b.

The first region 4a is a region of the channel layer 4 that is between the bottom of the source region 15 and the mean projected range as defined above. The second region 4b is a region of the channel layer 4 that is between the bottom of the channel layer 4 and the peak or the bottom end of the flat peak region and in which the impurity concentration gradient is negative. An impurity concentration of the mean projected range is an impurity concentration required in order for a leak current of the channel layer 4 to be operated in control, and is about 1×10¹⁷ cm⁻³, for example. Note that in this embodiment, in a case where the mean projected range is formed to be flat in a depth-wise direction of the trenches 7, the depth of the first region 4a is defined to reach a bottom end of a region (a flat region) which has the flat mean projected range. This will be described later.

In addition, the magnitude of impurity concentration gradient of the second region 4b is greater than that of the first region 4a. In the second region 4b, in particular, a region having an impurity concentration of approximately 1×10¹⁵ to 1×10¹⁶ cm⁻³ is a region having almost no influence on a substantial characteristic of the channel layer 4.

In this embodiment, as an example, the depth of the second region 4b is about 0.5 μm or less. In addition, the first region 4a having an impurity concentration needed by the channel layer 4 (1×10¹⁶ cm⁻³) is formed with a depth of about 0.8 μm from the top surface of the substrate 10. The depth of the channel layer 4 is approximately 1 μm from its top surface of the substrate 10.

Conventionally, in order to form a region having an impurity concentration needed by the channel layer 24, it has been unavoidable to form the second region 24b deeply. That has lead to needlessly deep formation of the channel layer 24.

In this embodiment, however, since the channel layer 4 is formed by way of high-acceleration ion implantations which will be described later, the depth of the second region 4b having a deep low impurity concentration profile can be considerably reduced. The second region 4b is a region including a lightly-doped impurity region which has almost no influence on a substantial characteristic of the channel layer 4. Additionally, since the depth is reduced while the impurity concentrations are kept the same, the region having the impurity concentration needed by the channel layer 4 can be maintained with a predetermined depth. Specifically, the channel layer 4 having a minimum necessary depth can be realized by reducing the second region 4b.

The depth of the channel layer 4 may vary depending on a performance level of the MOSFET. In this embodiment, however, the second region 4b can be formed with a different minimum necessary depth corresponding to any appropriately selected depth of the channel layer 4. This point will be described later.

By allowing the channel layer 4 to have a minimum necessary depth, it becomes unnecessary to form the trenches 7 needlessly deeply, and thereby, capacitance reduction of the MOSFET can be facilitated. Furthermore, in a case where it suffices to secure a breakdown voltage comparable to that of the deep second region used in the conventional structure, the depth of the epitaxial layer can be made thinner by a portion corresponding to the portion reduced of the channel layer 4. Because the depth of the epitaxial layer is a resistance component of the MOSFET, a reduction in the depth thereof enables the MOSFET to have a lower on-resistance.

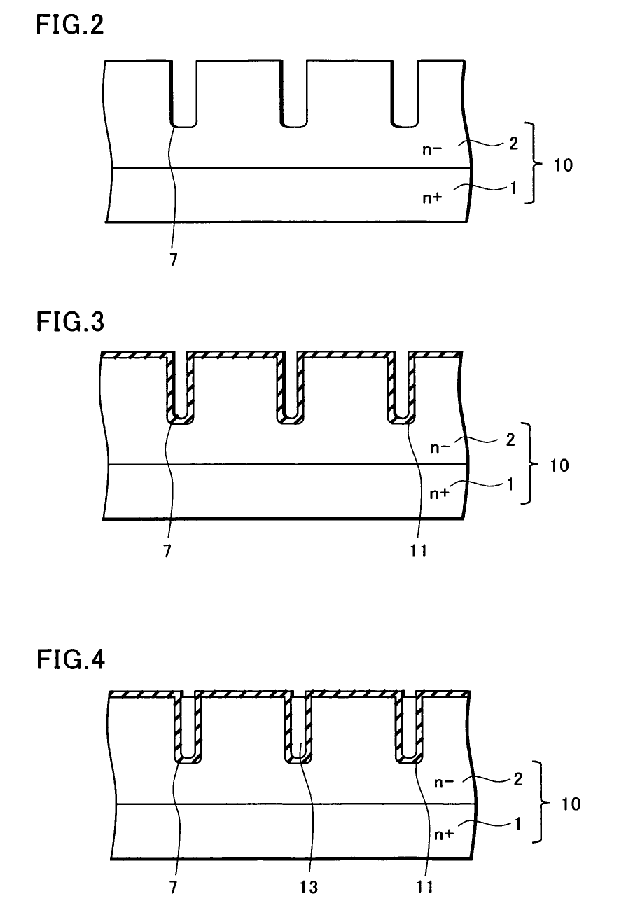

In FIG. 2 to 6C, a method of manufacturing the above-described MOSEFT is shown. The method of manufacturing the trench-type power MOSFET according to one embodiment of the present invention includes the steps of: forming trenches in a drain region formed of a semiconductor layer of one conductivity type, the semiconductor layer being stacked on a semiconductor substrate of the one conductivity type; forming an insulating film at least on an inner wall of each of the trenches; forming a gate electrode in each of the trenches; forming a channel layer, which has a substantially uniform depth from a top surface of the semiconductor layer, by implanting, into the top surface of the semiconductor layer, at plural different times, ions of an impurity of a conductivity type opposite to the one conductivity type; and forming source regions on the top surface of the semiconductor layer , next to the respective trenches, by implanting and diffusing ions of an impurity of the one conductivity type.

A first step (refer to FIG. 2) is a step of forming trenches in a drain region formed of a semiconductor layer of one conductivity type, the semiconductor layer being stacked on a semiconductor substrate of the one conductivity type.

First, a drain region 2 is formed by such a way as to stack an n− type epitaxial layer on an n+type silicon semiconductor substrate 1.

Next, the trenches are formed. Opening portions (not illustrated) of the respective trenches through which the epitaxial layer 2 is exposed are formed in the following manner: On the whole top surface of the drain region 2, a CVD oxide film (not illustrated) of NSG (non-doped silicate glass) is formed by using a CVD method. A mask formed of a resist film is formed on the whole top surface except portions on which the opening portions of trenches are intended to be formed, and the CVD oxide film is partially removed by dry etching the whole top surface.

Furthermore, by using the CVD oxide film as a mask, the epitaxial layer is dry etched by use of CF-based gas or HBr-based gas to form trenches 7. A depth for each of the trenches 7 is appropriately selected so that it can penetrate the channel layer which is intended to be formed in a later step.

A second step (refer to FIG. 3) is a step of forming an insulating film at least on an inner wall of each of the trenches.

Etching damages generated in dry etching are removed by applying dummy oxidation to form a dummy oxide film (not shown) on an inner wall of each of the trenches 7 and on a top surface of the channel layer 4. The dummy oxide film thus formed by the dummy oxidation, and the CVD oxide film which has become the mask, are simultaneously removed by use of an oxide film etchant such as hydrofluoric acid. Thereby, a stable gate oxide film can be formed. In addition, in this step, thermal oxidation under a high temperature allows the opening portions of the respective trenches 7 to be rounded off, and thereby, an effect of avoiding concentration of electric fields at each of the opening portions thereof is obtained. Afterward, a gate oxide film 11 is formed, that is, the gate oxide film 11 is formed with a thickness as appropriate according to a threshold voltage value by applying thermal oxidation (at a temperature of about 1000° C.) on the whole top surface, the thickness being, for example, a few to several hundred angstroms. The gate oxide film 11 is formed on the inner wall of each of the trenches 7.

A third step (refer to FIG. 4) is a step of forming a gate electrode in each of the trenches.

Additionally, on the whole top surface, a non-doped polysilicon layer is deposited, and high conductivity is intended to be obtained by implanting and diffusing phosphorus (P), for example, at a high concentration. Gate electrodes 13 embedded in the respective trenches 7 are formed by dry etching the polysilicon layer stacked on the whole top surface, without using a mask. Note that the gate electrodes 13 may be embedded in the respective trenches 7 by etching back the whole top surface, after depositing thereon polysilicon doped with an impurity.

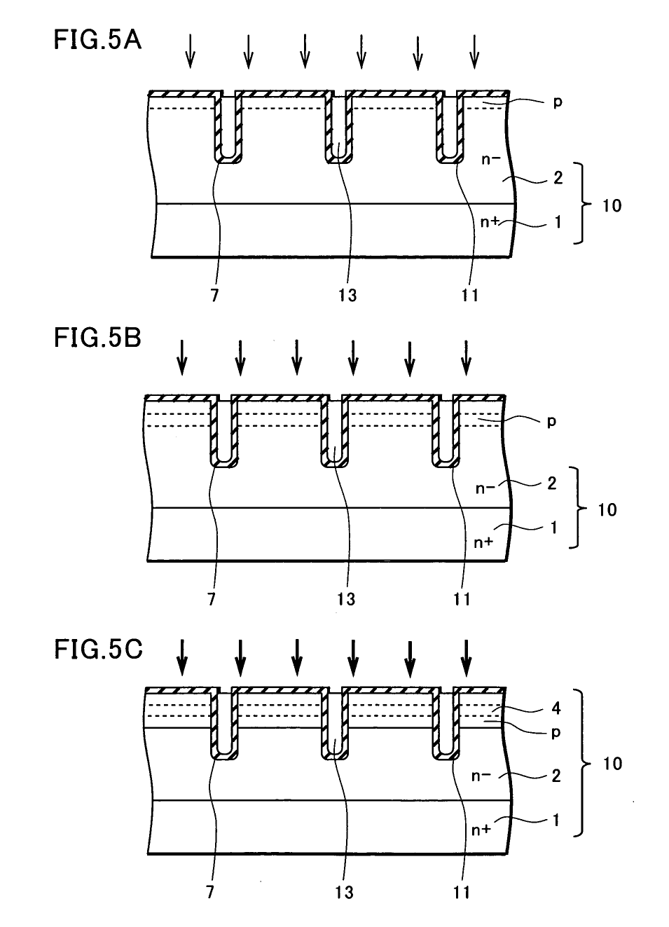

A fourth step (refer to FIGS. 5A to 5B) is a step of forming a channel layer, which has a predetermined depth from the top surface of the semiconductor layer, by implanting ions of an opposite conductivity type impurity a few times after the gate electrodes are formed.

Onto the whole top surface, ions of a p type impurity (such as boron) are implanted by applying a resist mask on regions where the channel layer is intended to be formed.

For each ion implantation in this step, a dose is about 1.2×10¹³ cm⁻², and at first, an high-acceleration ion implantation is carried out with an implantation energy of 100 keV (FIG. 5A). Next, the same dose of ions is implanted in succession to the first implantation while the implantation energy is set to be 200 keV (FIG. 5B). Furthermore, the same dose of ions is implanted while the implantation energy is set to be 300 keV. Thereby, the channel layer 4, which is an impurity-ion implanted layer, is formed (FIG. 5C). The ion implantation steps of the three different acceleration energies do not have to be performed in this order.

Thus, in this embodiment, the three different high-acceleration ion implantations are carried out with the respective different implant energies. Here, ions are implanted on the condition that impurity concentrations at a mean projected range become substantially uniform. In this manner, the mean projected range moves along side walls of the trenches on the respective occasions of ion implantations, and a first region 4a, which has an impurity concentration (1×10¹⁷ cm⁻³) necessary for the channel layer 4, is formed with a predetermined depth (1 μm or less from the top surface of the substrate 10). Incidentally, a depth mentioned here is an example, and the predetermined depth can be selected as appropriate according to implantation conditions. And a second region 4b is formed below the first region 4a.

Additionally, in this embodiment, a diffusion step using a heat treatment is made unnecessary, and the channel layer 4 is formed only by means of the ion implantations. Accordingly, in an impurity concentration profile of the second region 4b, a concentration distribution (Gaussian distribution) can be maintained from the time when the implantation is carried out. Specifically, the second region 4b with a shallow depth can be formed without forming a region which has a slow impurity concentration gradient and is conventionally formed as a by-product of thermal diffusion.

In the above manner, the channel layer 4 secures the first region. 4a having the necessary impurity concentration (about 1×10¹⁷ cm⁻³), and thus can be formed with a minimum necessary depth.

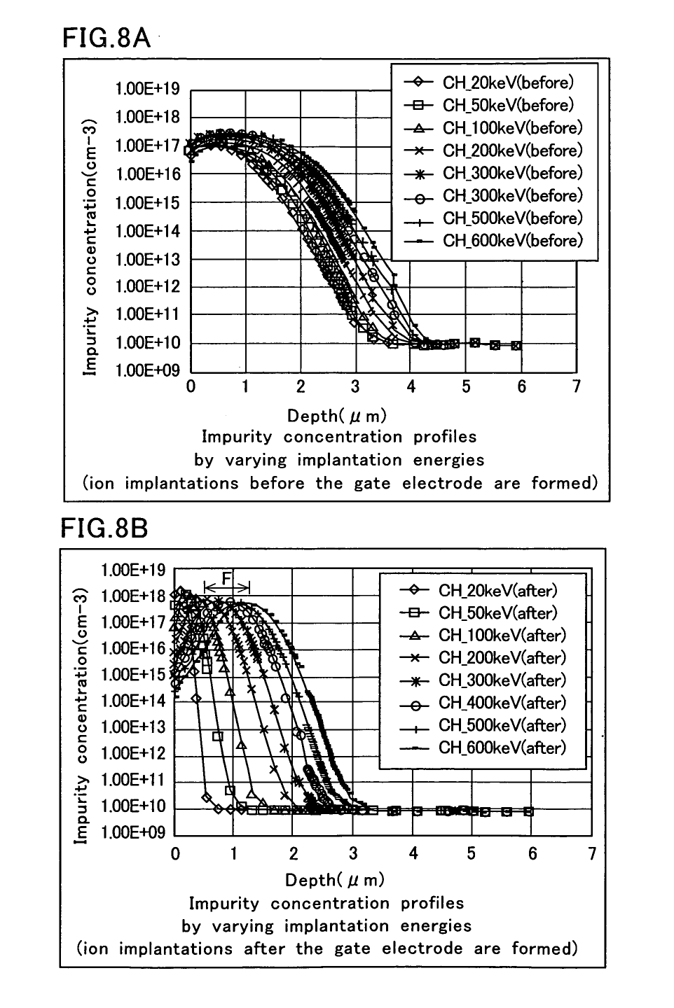

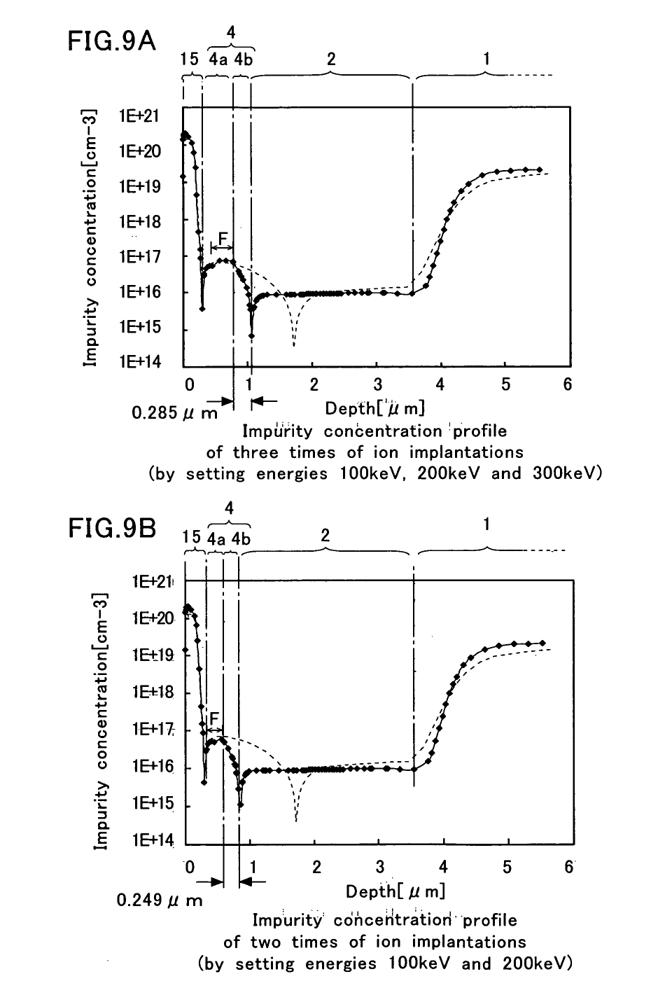

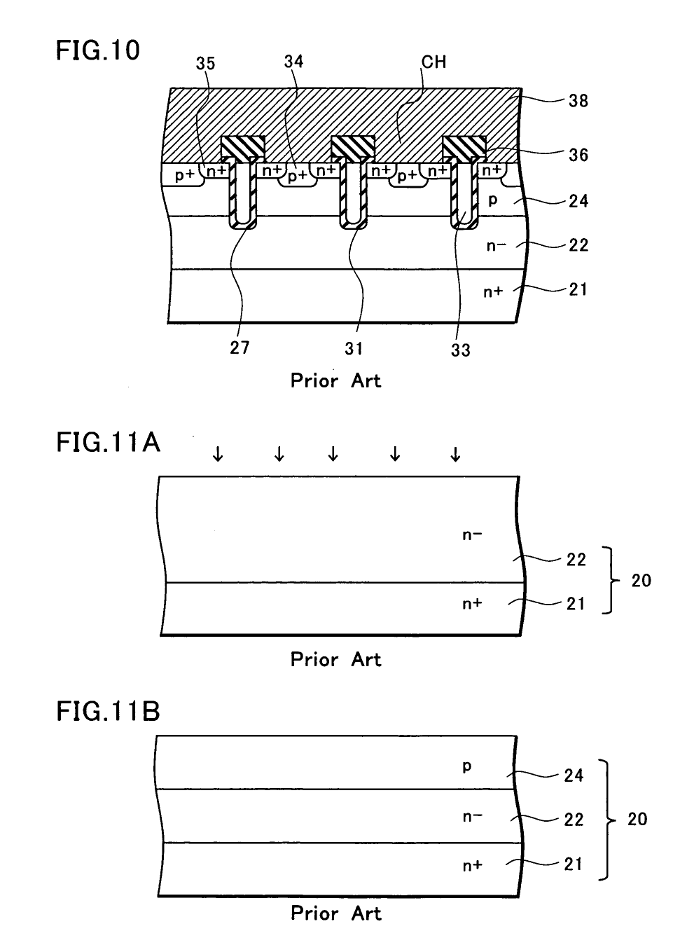

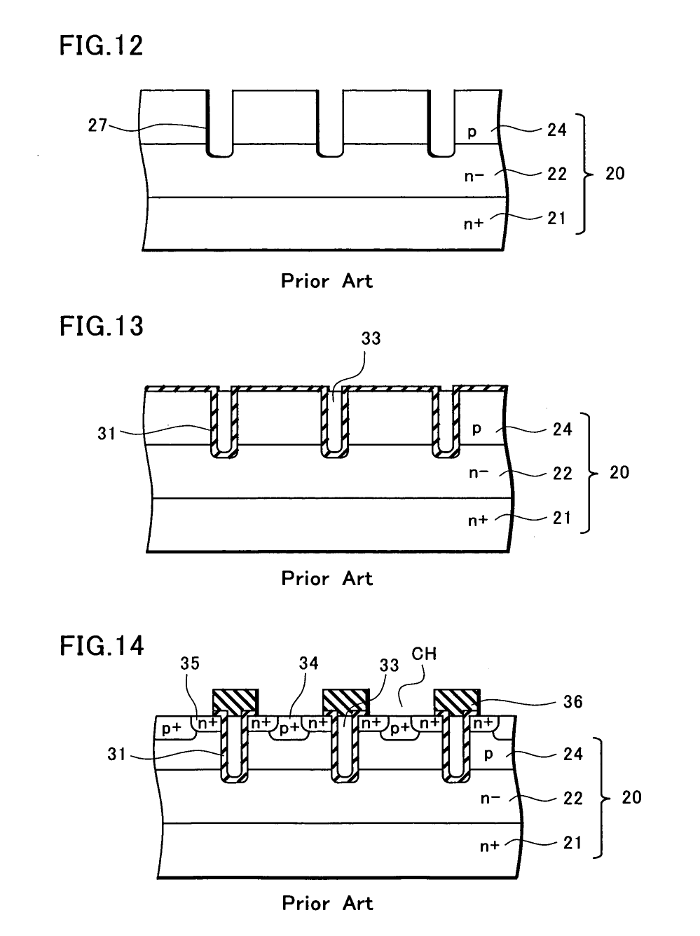

Furthermore, in this embodiment, the mean projected range can be formed in a flat form by changing the implantation energy in the ion implantation. Accordingly, the first region 4a which has an impurity concentration necessary for the channel layer 4 forms a substantially uniform depth in a depth-wise direction of the trenches 7. In addition, a flat region (a region which has a flat mean projected range, that is the first region 4a) can be enlarged or reduced by controlling the implantation energy. With regards to the impurity concentration profile, a description will be given later with reference to FIGS. 8A to 9B.

Note that heat treatment (at a temperature of about 900° C. and for about 60 minutes or at a temperature of about 1100° C .and for under 1 minute) may be applied after the forth step, the step of forming the channel layer having the predetermined depth, as long as the heat treatment is such that the impurity concentration profile of the second region 4b is substantially unchanged.

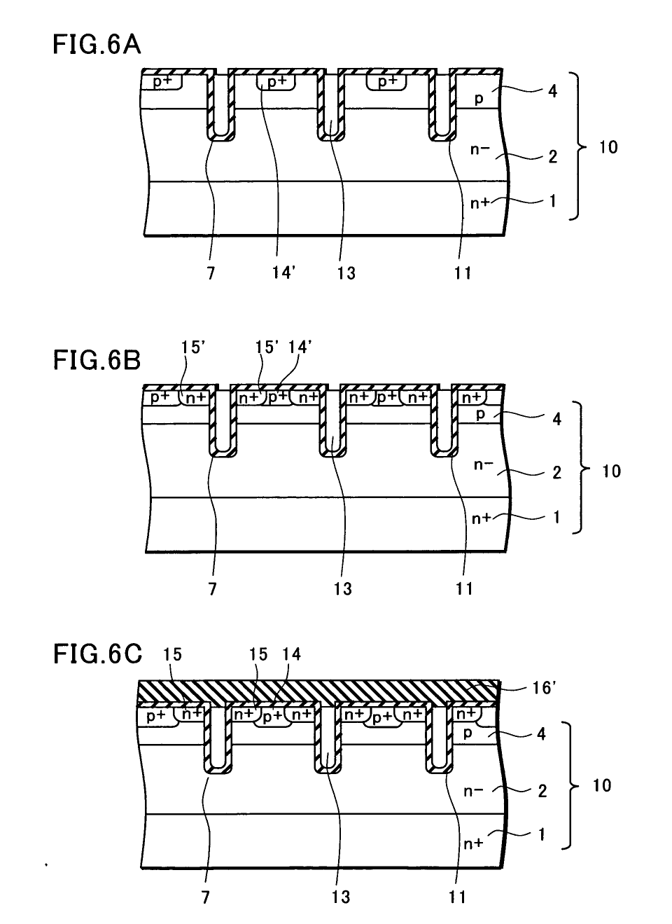

A fifth step (refer to FIGS. 6A to 6C) is a step of forming source regions on a top surface of the semiconductor layer, next to the respective trenches, by implanting and diffusing ions of one conductivity type.

In succession to the high-acceleration ion implantations of the channel layer 4, body regions serving to stabilize a potential of the substrate, and source regions are formed. Specifically, by using a mask formed of a resist film, ions of a p type impurity such as boron are selectively implanted into regions where the body regions are intended to be formed, and thereby p+ type impurity regions 14′ are formed. The ion implantation here is carried out with an implantation energy of 50 keV and a dose on the order of about 10¹⁵ cm⁻². After the p⁺ type impurity regions 14′ are formed, the resist film is removed (FIGS. 6A).

Additionally, n⁺ type impurity regions 15′ are formed in a way that: the whole top surface is covered by a mask while exposing the gate electrodes 13 and regions where the source regions are intended to be formed, the mask being formed of another resist film; and ions of an n type impurity such as arsenic are implanted by using the mask (FIGS. 6B). The ion implantation here is carried out with an implantation energy of 50 keV and a dose of about 5×10¹⁵ cm⁻².

Afterward, as shown in FIG. 6C, an insulating film 16′ of BPSG (boron phosphorus silicate glass) or the like, and a multilayered film are stacked on the whole top surface by means of a CVD method. The insulating film 16′ is intended to be an interlayer insulating film. As a result of a heat treatment (at a temperature of below 1000° C. and for about 60 minutes) applied at the time of this film formation, the p⁺ type impurity regions 14′ and the n⁺ type impurity regions 15′ are diffused. Thus formed are: the source regions 15 which are on the top surface of the substrate 10 and next to the respective trenches 7; and the body regions 14 each located between two adjacent ones of the source regions 15.

The heat treatment in this case requires a time that is sufficiently less than the time (a few to several hours) taken for the heat treatment in the conventional method of channel layer formation, and uses a temperature that is lower than temperatures (1000° C. or higher) used in the trench formation step and in the gate oxide film formation step of this embodiment. In the meantime, conditions for the high-acceleration ion implantations for the channel layer 4 are not limited to the ones described in the above example, but such conditions for the implantations are selected as appropriate in order that the channel layer 4 may be unaffected from the heat treatment in this step.

In other words, with the heating conditions of this step, diffusion of the impurity implanted into the channel layer 4 hardly progresses, and has no influence on the impurity concentration profile of the channel layer 4. Accordingly, the shallow channel layer 4, in which the second region 4b is sufficiently shallow and in which variation in impurity concentration profile due to depletion is avoided, can be realized.

Note that the formation of the p⁺ type impurity region 14′ may follow the formation of the n⁺ type impurity region 15′, although the formation of the n⁺ type impurity region 15′ follows the formation of the p⁺ type impurity region 14′ in this embodiment.

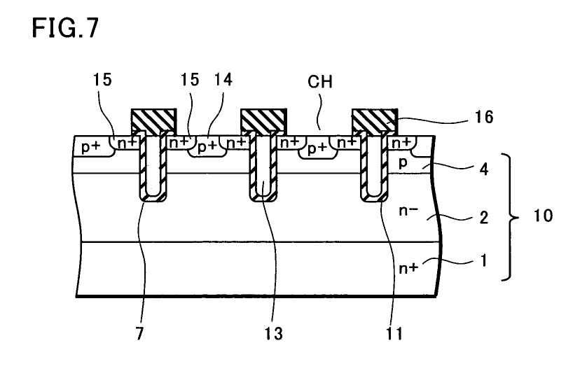

A sixth step (refer to FIG. 7) is a step of forming a metal wiring layer which makes a contact with the respective source regions 15.

By using a resist film as a mask, the insulating film 16′ are etched. In that way, at the same time when interlayer insulating films 16 at least on the respective gate electrodes 13 are allowed to remain, contact holes CH through which the source regions 15 and the body regions 14 are exposed are formed.

Then, for the purpose of inhibiting a silicon nodule and preventing spike (interdiffusion between metal and a silicon substrate), a barrier metal layer (not illustrated) formed of a titanium-based material is formed before the metal wiring layer (source electrode) is formed.

Thereafter, on the whole top surface, aluminum alloy, for example, is spattered to be a metal film having a film thickness of about 5000 angstroms. Afterward, an alloying heat treatment is applied in order to stabilize an interface between the metal film and the silicon surface. This heat treatment is conducted in hydrogen-containing gas, at a temperature in a range between 300 and 500° C. (about 400° C., for example) and for about 30 minutes. Thereby, crystal deformation in the metal film is removed, and the interface therebetween is stabilized. The source regions 15 and the body regions 14 are electrically connected to the metal film through the contact holes CH. The metal film is patterned in a predetermined configuration to form the metal wiring layer 18.

Furthermore, SiN or the like, which becomes a passivation film, is provided, although the passivation film is not illustrated. Additionally thereafter, for the purpose of removing damages, a heat treatment is applied at a temperature of 300 to 500° C. (400° C., for example) and for about 30 minutes.

FIGS. 8A and 8B show impurity concentration profiles of boron which is an impurity for the channel layer 4. FIG. 8A shows impurity concentration profiles obtained in a state where a heat treatment for forming the trenches and the gate oxide film has been applied after boron ions are implanted and diffused by using a high-acceleration ion implantation system. On the other hand, FIG. 8B shows impurity concentration profiles obtained in a state where boron ions have been implanted by using a high-acceleration ion implantation system after the trenches and the gate oxide film are formed, as in the method of this embodiment. To simulate each of these states, different simulations are conducted with different implant energies.

FIG. 8A indicates that an impurity concentration profile is made spread out with a slow gradient in a region below the mean projected range if the heat treatment for forming the trenches, the gate oxide film and the like at a high temperature (1000° C. or higher) is applied after an ion implantation, even though the ion implantation is carried out by using the high-acceleration ion implantation system.

On the other hand, if a diffusion using a heat treatment is not applied after an ion implantation as in the case of FIG. 8B, an impurity concentration profile (distribution) in a region below the mean projected range can be maintained as a Gaussian distribution. This embodiment excludes a heat treatment at a high temperature after a high-acceleration ion implantation, whereby the shallow second region 4b is realized.

Moreover, as described in the drawing, by varying implantation energies among different occasions of high-acceleration ion implantations, ions can be implanted in the different depth while an impurity concentration at the mean projected range is maintained substantially uniform. That is, since the flat region F where the mean projected range is flat can be enlarged or reduced, the channel layer 4 can be formed with a desired depth and also the depth of the second region 4b can be made shallow.

In addition, in this embodiments, not only since the diffusion step of the channel layer is unnecessary but also since ion implantations of the channel layer are carried out after forming trenches and a gate oxide film, it becomes possible to allow the channel layer to be unaffected from a high-temperature heat treatment, and to avoid variation in impurity concentration profile, the variation resulting from depletion.

Here, assume a case where, after the gate electrodes are formed, the channel layer is formed by taking a method of implanting ions (at 30 keV) with a conventional ion implantation system. In the case of this ion implantation system, an implantation energy is so low that, as shown in FIG. 8A, the mean projected ranges cannot be made deeply. In other words, a diffusion step using a heat treatment becomes necessary in order to form a region, which has an impurity concentration needed by the channel layer, at a predetermined depth. In this case, even though the channel layer is formed after the gate electrodes are formed, an impurity concentration profile of the channel layer cannot be formed shallowly.

FIGS. 9A and 9B show impurity concentration profiles of the source regions 15, the channel layer 4, and the n⁻ type epitaxial layer 2 and the semiconductor substrate 1 according to this embodiment. In each of these figures, the longitudinal axis indicates impurity concentrations, and lateral axis indicates depths from the surface of the substrate 10. FIG. 9A corresponds to the case in which ions are implanted at three different times by setting implant energies to be 100 keV, 200 keV and 300 keV, respectively. FIG. 9B corresponds to the case in which ions are implanted at two different times by setting implant energies to be 100 keV and 200 keV, respectively. And the impurity concentration profiles in the conventional case (FIG. 15B) shown in FIGS. 9A and 9B are respectively indicated by dashed lines for the purpose of the comparison.

As evidenced by these figures, according to the present embodiment, the second region 4b can be considerably reduced, the second region 4b including a lightly-doped impurity region which has almost no influence on a characteristic of the channel layer 4. In addition, depending on a number of times of ion implantations and also depending on implant energies of the ion implantations, the region which has an impurity concentration needed by the channel layer 4 (the flat region F in which the mean projected range is flat, that is the first region 4a) can be enlarged or reduced, and thereby the depth of the channel layer 4 can be controlled.

That is to say, the channel layer 4 having a desired depth can be actualized as a minimum necessary depth. Thereby, each of the trenches 7 penetrating the channel layer 4 is also allowed to have a minimum necessary depth, and a capacitance of the MOSFET can be reduced in each of the aforementioned cases.

For example, under the implantation conditions in each of FIGS. 9A and 9B, the channel layer 4 can be formed more shallowly than the channel layer in the conventional case shown in FIG. 15. Specifically, the depth of the second region 4b is about 0.29 μm in the case where ions have been implanted at the three times, and is about 0.25 μm in the case where ions have been implanted at the two times. Additionally, the depth of the channel layer 4 from the surface of the substrate 10 is about 1.0 μm in the case where ions have been implanted at the three times, and is about 0.8 μm in the case where ions have been implanted at the two times.

That the channel layer 4 is shallowly formed means that: a depth (thickness) of the n⁻ type epitaxial layer 2 is increased, the depth spanning from its interface with the channel layer 4 to its interface with the n⁺ type semiconductor substrate 1, given that the n⁻ type epitaxial layer 2 and the n⁺ type semiconductor substrate 1 are the same as those in the conventional case. That is, in a case where it suffices to secure a breakdown voltage at the same level as secured in the conventional case, the depth of the n⁻ type epitaxial layer 2 can be reduced. Since the n⁻ type epitaxial layer 2 becomes a resistance component of the MOSFET, the reduction in depth of the n⁻ type epitaxial layer 2 leads to a reduction in on resistance of the MOSFET.

Furthermore, an impurity concentration and an impurity implant depth can be precisely controlled depending on an electrical quantity such as: a current in a ion implantation; a time taken for an ion implantation; and an implantation energy. Therefore, accuracy, controllability and reproducibility of doping are extremely high, and thus, a desired depth of the channel layer can be obtained by changing implantation energy.

Hereinabove, in the embodiments of the present invention, the n-channel type MOSFET has been described as an example. However, the embodiment of the present invention can be also applicable to a p-channel type MOSFET in a similar manner. Furthermore, the embodiment of the invention has no restriction on this point, and can also be applicable to IGBT and other semiconductor elements of an insulated gate type in a similar manner.

According to the embodiment of the present invention, first, it is possible to reduce a depth of the second region whose impurity concentration profile has a large gradient as an absolute value. In the conventional method, when a region having an impurity concentration needed by the channel layer was formed, depth of the second region was inevitably determined and was uncontrollable. Furthermore, the second region had a deep depth since a slow concentration gradient was formed in the second region, and that deep depth has been a factor to cause the channel layer to be formed unnecessarily deeply. However, according to this embodiment, it is made possible to form the second region shallowly by forming a region having a necessary impurity concentration. Accordingly, a depth of the channel layer can be controlled.

Secondly, since the channel layer is an ion-implanted layer, a manufacturing cost can be reduced as compared with a case where the channel layer is formed of an epitaxial layer.

Thirdly, the channel layer is formed by means of high-acceleration ion implantations carried out at plural different times, after the trenches and the gate oxide film are formed. Therefore, since a thermal treatment step for a long period of time that follows the ion implantations is excluded, the second region can be made considerably smaller. Additionally, since a thermal treatment step at a high temperature (1000° C. or higher) that follows the ion implantations is excluded, it is possible to inhibit variation in the impurity concentration profile, the variation resulting from depletion.

Fourthly, the ion implantations into the channel layer are carried out at plural different times in which different implant energies are applied respectively, in order that an impurity concentration at the mean projected range can be substantially uniform. Therefore, a region having an impurity concentration needed by the channel layer can be formed to have a desired depth. In this condition, the second region can be considerably reduced. Accordingly, the channel layer having the desired depth can be formed to have a minimum necessary depth.

Fifthly, an impurity concentration and an impurity implant depth can be precisely controlled depending on an electrical quantity such as: a current in a ion implantation; a time taken for an ion implantation; and an implantation energy. Therefore, accuracy, controllability and reproducibility of doping are extremely high, and thus, a desired depth of the channel layer can be obtained by changing implantation energy.

By forming the channel layer (an impurity concentration profile thereof) shallowly according to the embodiment of the present invention, for example, it becomes possible to form the trenches shallowly, therefore it becomes possible to reduce a capacitance of a semiconductor device of an insulated gate type. Additionally, since the channel layer is made shallow, room is generated in the epitaxial layer which becomes a drain region. That is, in a case where a breakdown voltage at the same level as that in the conventional case is intended to be secured, a thickness (depth) of the epitaxial layer can be reduced, and hence reduction in on resistance can be realized.

What is claimed is:

1. A semiconductor device comprising:
a semiconductor substrate;
a drain region disposed on the semiconductor substrate;
a channel layer disposed on the drain region;
a trench penetrating the channel layer to reach the drain region;
a gate electrode disposed in the trench;
an insulating film disposed between an inner wall of the trench and the gate electrode; and
a source region formed in the channel layer and adjacent the trench,
wherein an impurity concentration profile of the channel layer in a depth direction thereof has a peak or a flat peak region, and a distance between a bottom of the source region and the peak or an bottom end of the flat peak region is larger than a distance between an bottom of the channel layer and the peak or the bottom end of the flat peak region.

2. The semiconductor device of claim 1, wherein the distance between the bottom of the channel layer and the peak or the bottom end of the flat peak region is less than 0.5 μm.

3. The semiconductor device of claim 1, wherein the impurity profile comprises a combination of two or more impurity profiles each formed by ion implantation.

4. The semiconductor device of claim 1, wherein the flat peak region of the impurity concentration profile starts at the bottom of the source region.

5. A method of manufacturing a semiconductor device, comprising:
providing a semiconductor substrate of a first general conductivity type;
depositing a semiconductor layer of the first general conductivity type on the semiconductor substrate;
forming a trench in the semiconductor layer;
forming an insulation film to cover an inner wall of the trench;
forming a gate electrode in the trench covered by the insulation film;
performing a first impurity implantation of the semiconductor layer after the formation of the gate electrode;
performing a second impurity implantation of the semiconductor layer after the first impurity implantation; and
forming a region of the first general conductivity type in the semiconductor layer and adjacent the trench.

6. The method of claim 5, wherein an acceleration energy of the first impurity implantation is different from an acceleration energy of the second impurity implantation.

7. The method of claim 6, wherein the acceleration energies are 100 keV or higher.

8. The method of claim 5, wherein the region of the first general conductivity type is formed by a third impurity implantation and a thermal diffusion of impurities implanted by the third impurity implantation.

9. The method of claim 8, wherein the third impurity implantation is performed after the first and second impurity implantations.

10. The method of claim 5, wherein the first and second impurity implantations are performed so that a channel layer of a second general conductivity type is formed in the semiconductor layer without heat treatments required to diffuse implanted impurities further into the semiconductor layer.

11. The method of claim 10, further comprising a third impurity implantation of the semiconductor layer after the second impurity implantation so that a channel layer having a predetermined depth is formed after the first, second and third impurity implantations without heat treatment.

12. The method of claim 10, wherein the region of the first general conductivity type is formed by a third impurity implantation and a thermal diffusion of impurities implanted by the third impurity implantation.
